(19) United States
(12) Patent Application Publication
(10) Pub. No.: US 2025/0201692 A1
(43) Pub. Date: Jun. 19, 2025

(54) PACKAGE STRUCTURE AND METHOD OF FABRICATING THE SAME

(71) Applicant: Taiwan Semiconductor Manufacturing Company, Ltd., Hsinchu (TW)

(72) Inventors: Ping-Yin Hsieh, Hsinchu City (TW); Chih-Hao Chen, Taipei City (TW); Li-Hui Cheng, New Taipei City (TW); Ying-Ching Shih, Hsinchu City (TW)

(73) Assignee: Taiwan Semiconductor Manufacturing Company, Ltd., Hsinchu (TW)

(21) Appl. No.: 18/403,754

(22) Filed: Jan. 4, 2024

Related U.S. Application Data
(60) Provisional application No. 63/609,872, filed on Dec. 14, 2023.

(51) Int. Cl. H01L 23/498; H01L 23/00; H01L 23/31; H01L 25/00; H01L 25/065

(52) U.S. Cl. CPC H01L 23/49838; H01L 23/3121; H01L 23/49822; H01L 24/16; H01L 24/32; H01L 24/73; H01L 25/0655; H01L 25/50; H01L 2224/16227; H01L 2224/32225; H01L 2224/73204; H01L 2924/181

(57) ABSTRACT

A package structure includes a circuit substrate, a semiconductor package, a thermal interface material structure, a plating layer, a first intermetallic compound, a second intermetallic compound and a lid structure. The semiconductor package is disposed on the circuit substrate and includes a center region and peripheral regions. The thermal interface material structure is disposed on the center region and on the peripheral regions of the semiconductor package. The plating layer is disposed on the thermal interface material structure. The first intermetallic compound is formed in between the thermal interface material structure and the plating layer over the center region. The second intermetallic compound is formed in between the thermal interface material structure and the plating layer over the peripheral regions of the semiconductor package, wherein the second intermetallic compound is different from the first intermetallic compound. The lid structure is disposed on the circuit substrate and covering the semiconductor package.

### CROSS-REFERENCE TO RELATED APPLICATION

This application claims the priority benefit of U.S. provisional application Ser. No. 63/609,872, filed on Dec. 14, 2023. The entirety of the above-mentioned patent application is hereby incorporated by reference herein and made a part of this specification.

### BACKGROUND

Semiconductor devices and integrated circuits used in a variety of electronic applications, such as cell phones and other mobile electronic equipment, are typically manufactured on a single semiconductor wafer. The dies of the wafer may be processed and packaged with other semiconductor devices or dies at the wafer level, and various technologies have been developed for the wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1A to FIG. 8 are schematic top and sectional views of various stages in a method of fabricating a semiconductor package according to some exemplary embodiments of the present disclosure.

FIG. 9 is a schematic sectional view of a semiconductor package according to some other exemplary embodiments of the present disclosure.

FIG. 10 to FIG. 15 are schematic top and sectional views of various stages in a method of fabricating a package structure according to some exemplary embodiments of the present disclosure.

FIG. 16 is a schematic sectional view of a package structure according to some other exemplary embodiments of the present disclosure.

FIG. 17 to FIG. 20 are schematic top and sectional views of various stages in a method of fabricating a package structure according to some other exemplary embodiments of the present disclosure.

FIG. 21 is a schematic sectional view of a package structure according to some other exemplary embodiments of the present disclosure.

FIG. 22 is a schematic sectional view of a package structure according to some other exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In current applications, some packages are designed with thermal interface material structures on the backside for high heat dissipation. However, during a reflow process for joining conductive terminals to a substrate of the packages, a material loss of different thermal interface materials may occur at different regions of the package. For example, when indium (In) is used as the thermal interface material, material loss was found at peripheral regions of the package, and when indium-silver (In10Ag) is used as the thermal interface material, material loss was found at center regions of the package during the reflow process. The material loss of the thermal interface material during the reflow process may be caused by different factors such as the material properties, warpage performance of the package, the lid design and reflow profiles. In some embodiments of the present disclosure, heat dissipation components with mixed thermal interface materials was used to avoid the material loss issue.

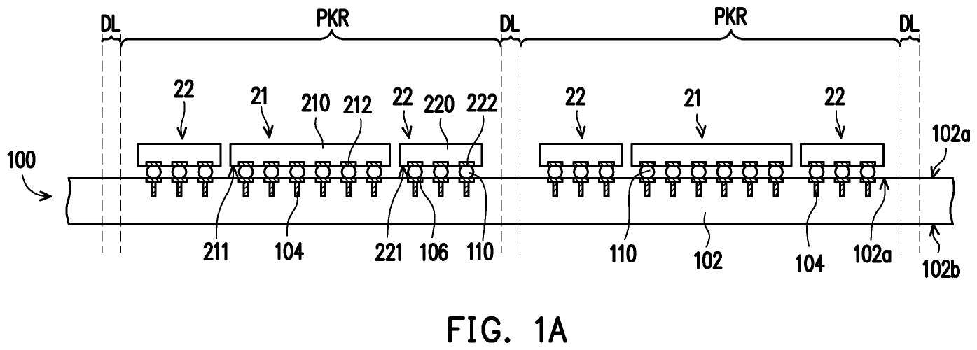

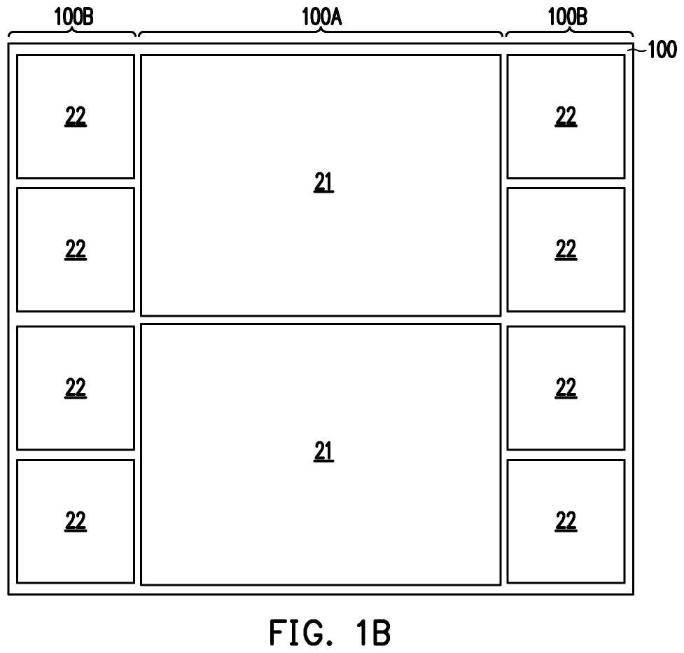

FIG. 1A to FIG. 8 are schematic top and sectional views of various stages in a method of fabricating a semiconductor package according to some exemplary embodiments of the present disclosure. Referring to FIG. 1A, an interposer structure 100 (or interconnection structure) is provided. In some embodiments, the interposer structure 100 includes a core portion 102, and a plurality of through vias 104 and with conductive pads 106 formed therein. In some embodiments, the core portion 102 is a substrate such as a bulk semiconductor substrate, silicon on insulator (SOI) substrate or a multi-layered semiconductor material substrate. In some embodiments, the semiconductor material of the substrate (core portion 102) include silicon, germanium, silicon germanium, silicon carbide, gallium arsenic, gallium phosphide, indium phosphide, indium arsenide, indium antimonide, GaAsP, AlInAs, AlGaAs, GaInAs, GaInP, GaInAsP, or combinations thereof. In some embodiments, the core portion 102 is doped or undoped.

As illustrated in FIG. 1A, the conductive pads 106 are formed on a first surface 102a of the core portion 102. In some embodiments, through vias 104 are formed in the core portion 102 and connected with the conductive pads 106. In some embodiments, the through vias 104 extend into the core portion 102 with a specific depth. In some embodiments, the through vias 104 are through-substrate vias. In some embodiments, the through vias 104 are through-silicon vias when the core portion 102 is a silicon substrate. In some embodiments, the through vias 104 are formed by forming holes or recesses in the core portion 102 and then filling the recesses with a conductive material. In some embodiments, the recesses are formed by, for example, etching, milling, laser drilling or the like. In some embodiments, the conductive material is formed by an electro-chemical plating process, chemical vapor deposition (CVD), atomic layer deposition (ALD) or physical vapor deposition (PVD), and the conductive material may include copper, tungsten, aluminum, silver, gold or a combination thereof. In some embodiments, the conductive pads 106 connected with the through vias 104 are formed as conductive parts of the redistribution layer(s) formed on the interposer structure 100. In some embodiments, the conductive pads 106 include under bump metallurgies (UBMs). In certain embodiments, the interposer structure 100 may further include active or passive devices, such as transistors, capacitors, resistors, or diodes passive devices formed in the core portion 102.

As further shown in FIG. 1A, the core portion 102 has a plurality of package regions PKR and a dicing lane DL separating each of the plurality of package regions PKR. The through vias 104 and conductive pads 106 are formed in the core portion 102 within the package regions PKR. In some embodiments, a plurality of semiconductor dies 21 (first semiconductor dies) and a plurality of semiconductor dies 22 (second semiconductor dies) are provided on the interposer structure 100, or on the core portion 102 within the package regions PKR. The semiconductor dies 21 and semiconductor dies 22 are individual dies singulated from a wafer. In some embodiments, the semiconductor dies 21 contain the same circuitry, such as devices and metallization patterns, or the semiconductor dies 21 are the same type of dies. In some embodiments, the semiconductor dies 22 contain the same circuitry, or the semiconductor dies 22 are the same type of dies. In certain embodiments, the semiconductor dies 21 and the semiconductor dies 22 have different circuitry or are different types of dies. In some embodiments, the semiconductor dies 21 and the semiconductor dies 22 may have the same circuitry.

In some embodiments, the semiconductor dies 21 are major dies, while the semiconductor dies 22 are tributary dies. As illustrated in FIG. 1B, the major dies (semiconductor dies 21) are arranged on the core portion 102 in a central region 100A of the interposer structure 100 (interconnection structure) in each package region PKR. The tributary dies (semiconductor dies 22) are disposed over a peripheral region 100B of the interposer structure 100 (interconnection structure), and arranged side-by-side and spaced apart from the major dies. In some embodiments, the tributary dies are arranged aside the major dies, and around or surrounding the major dies. In one embodiment, four, six or eight tributary dies are arranged around each of the major dies per one package region PKR. For example, as shown in FIG. 1B, in one exemplary embodiment, four semiconductor dies 22 (tributary dies) are surrounding each of the semiconductor dies 21 (major dies) in each of the package region PKR.

Referring back to FIG. 1A, in some embodiments, the semiconductor dies 21 has a surface area larger than that of the semiconductor dies 22. Also, in some embodiments, the semiconductor dies 21 and the semiconductor dies 22 are of different sizes, including different surface areas and/or different thicknesses. In some embodiments, the semiconductor dies 21 are a logic die, including a central processing unit (CPU) die, graphics processing unit (GPU) die, system-on-a-chip (SoC) die, a microcontroller or the like. In some embodiments, the semiconductor dies 21 is a power management die, such as a power management integrated circuit (PMIC) die. In some embodiments, the semiconductor dies 22 are a memory die, including dynamic random access memory (DRAM) die, static random access memory (SRAM) die or a high bandwidth memory (HBM) die. In some other embodiments, the semiconductor dies 22 are dummy dies, which do not perform any electrical functions. The disclosure is not limited thereto, and the number, sizes and types of the semiconductor die disposed on the core portion 102 may be appropriately adjusted based on product requirement.

As illustrated in FIG. 1A, the semiconductor dies 21 include a body 210 and connecting pads 212 formed on an active surface 211 of the body 210. In certain embodiments, the connecting pads 212 may further include pillar structures for bonding the semiconductor dies 21 to other structures. In some embodiments, the semiconductor dies 22 include a body 220 and connecting pads 222 formed on an active surface 221 of the body 220. In other embodiments, the connecting pads 222 may further include pillar structures for bonding the dies 22 to other structures.

In some embodiments, the semiconductor dies 21 and the semiconductor dies 22 are attached to the first surface 102a of the core portion 102, for example, through flip-chip bonding by way of the electrical connectors 110. Through a reflow process, the electrical connectors 110 are formed between the connecting pads 212, 222 and conductive pads 106, and are physically connecting the semiconductor dies 21, 22 to the core portion 102 of the interposer structure 100. In some embodiments, the electrical connectors 110 are located in between the semiconductor dies 21, 22 and the interposer structure 100. In certain embodiments, semiconductor dies 21, 22 are electrically connected to the through vias 104 and the conductive pads 106 through the electrical connectors 110. In some embodiments, when the semiconductor dies 22 are dummy dies, the semiconductor dies 22 may be attached to the electrical connectors 110 through physical connection without establishing an electrical connection thereto. In other words, the connecting pads 222 of the semiconductor dies 22 may be dummy pads, for example.

In some embodiments, the electrical connectors 110 are micro-bumps, such as micro-bumps having copper metal pillars. In another embodiment, the electrical connectors 110 are solder bumps, lead-free solder bumps, or micro bumps, such as controlled collapse chip connection (C4) bumps or micro bumps containing copper pillars. In some embodiments, the bonding between the semiconductor dies 21, 22 and the core portion 102 is solder bonding. In some embodiments, the bonding between the semiconductor dies 21, 22 and the core portion 102 is direct metal-to-metal bonding, such as copper-to-copper bonding.

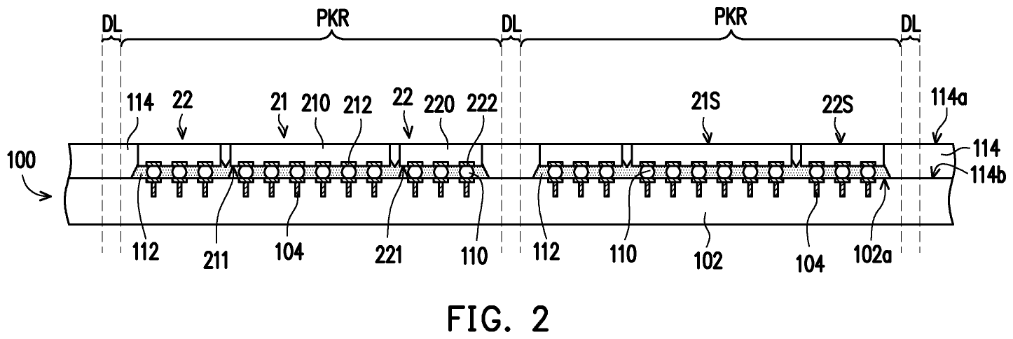

Referring to FIG. 2, in a subsequent step, an underfill structure 112 may be formed to cover the plurality of electrical connectors 110, and to fill up the spaces in between the semiconductor dies 21, 22 and the interposer structure 100. In some embodiments, the underfill structure 112 further cover side walls of the semiconductor dies 21, 22, and is located within the package region PKR. Thereafter, an insulating encapsulant 114 (or molding compound) may be formed over the interposer structure 100 (or over the core portion 102) to cover the underfill structure 112, and to surround the semiconductor dies 21 and 22.

In some embodiments, the insulating encapsulant 114 is formed on the first surface 102a of the core portion 102 in the package regions PKR and over the dicing lanes DL. In some embodiments, the insulating encapsulant 114 is formed through, for example, a compression molding process or transfer molding. In one embodiment, a curing process is performed to cure the insulating encapsulant 114. In some embodiments, the semiconductor dies 21, 22 and the electrical connectors 110 are encapsulated by the insulating encapsulant 114. In some embodiments, a planarization process, including grinding or polishing, is performed to partially remove the insulating encapsulant 114, exposing backside surfaces 21S, 22S of the semiconductor dies 21, 22. Accordingly, the backside surfaces 21S, 22S of the semiconductor dies 21, 22 are levelled with a top surface 114a of the insulating encapsulant 114. The top surface 114a being opposite to a backside surface 114b of the insulating encapsulant 114, wherein the backside surface 114b is in contact with the core portion 102. In some alternative embodiments, the backside surfaces 21S, 22S of the semiconductor dies 21, 22 are not exposed from the insulating encapsulant 114, and are well protected by the insulating encapsulant 114.

In some embodiments, a material of the insulating encapsulant 114 includes polymers (such as epoxy resins, phenolic resins, silicon-containing resins, or other suitable resins), dielectric materials having low permittivity (Dk) and low loss tangent (Df) properties, or other suitable materials. In another embodiment, the insulating encapsulant 114 may include an acceptable insulating encapsulation material. In some embodiments, the insulating encapsulant 114 may further include inorganic filler or inorganic compound (e.g. silica, clay, and so on) which can be added therein to optimize coefficient of thermal expansion (CTE) of the insulating encapsulant 114. The disclosure is not limited thereto.

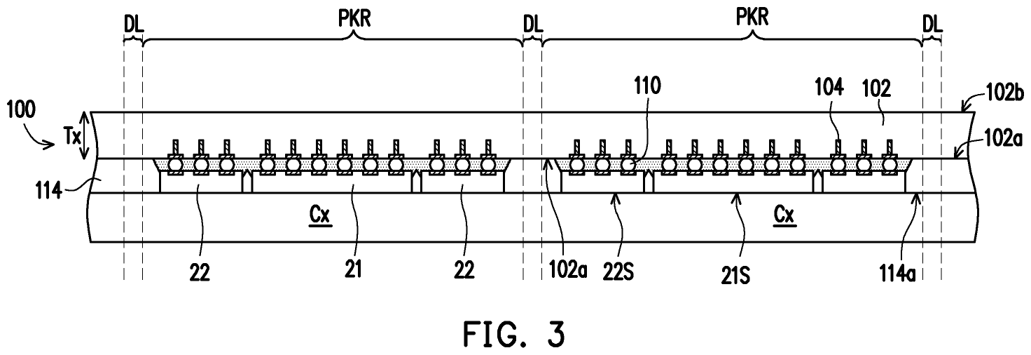

Referring to FIG. 3, after forming the insulating encapsulant 114, the structure shown in FIG. 2 is turned upside down or flipped, and placed on a carrier Cx, so that the carrier Cx directly contacts the backside surfaces 21S, 22S of the semiconductor dies 21, 22 and the top surface 114a of the insulating encapsulant 114. As shown in FIG. 3, at this stage of processing, the interposer structure 100 has not been thinned and has a thickness Tx. In other words, the through vias 104 are not revealed, and are embedded in the core portion 102 of the interposer structure 100.

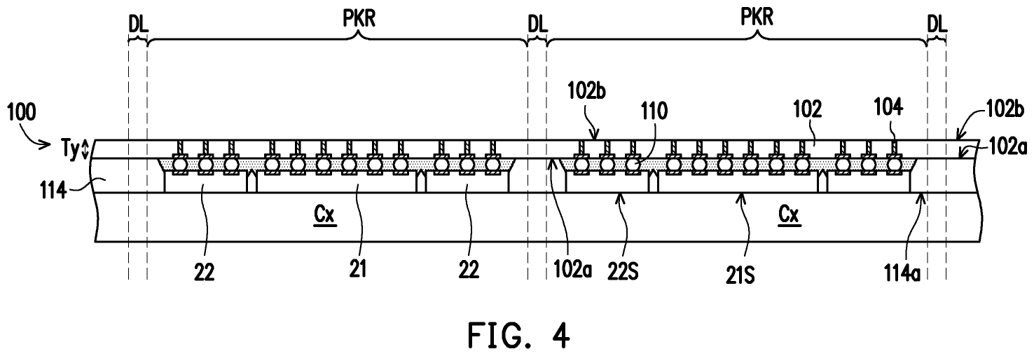

Referring to FIG. 4, a thinning process is performed to the interposer structure 100 to partially remove or thin the core portion 102 of the interposer structure 100 until the through vias 104 are exposed and a second surface 102b of the core portion 102 is formed. In some embodiments, the thinning process may include a back-grinding process, a polishing process or an etching process. In some embodiments, after the thinning process, the interposer structure 100 is thinned to a thickness Ty. In some embodiments, a ratio of the thickness Ty to the thickness Tx ranges from about 0.1 to about 0.5.

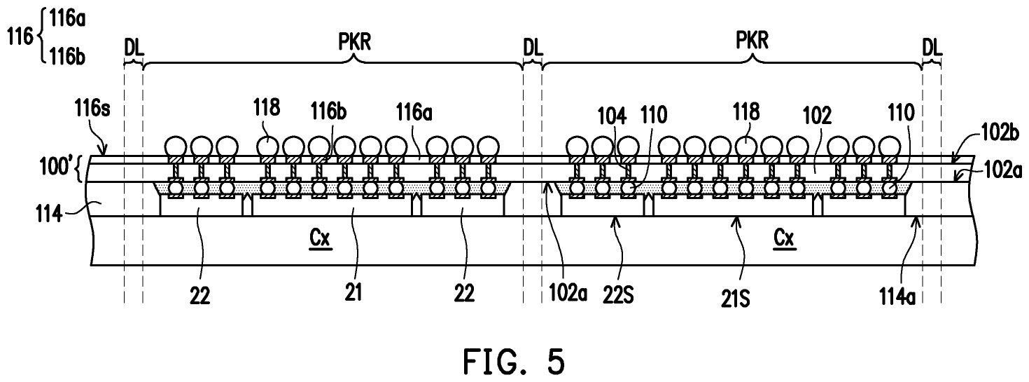

Referring to FIG. 5, a redistribution structure 116 is formed on the second surface 102b of the core portion 102 in the package region PKR and over the dicing lanes DL. The second surface 102b being opposite to the first surface 102a of the core portion 102. In some embodiments, the redistribution structure 116, the core portion 102, the through vias 104 and conductive pads 106 constitutes the interposer structure 100′. In some embodiments, the redistribution structure 116 electrically connects the through vias 104 and/or electrically connects the through vias 104 with external devices. In certain embodiments, the redistribution structure 116 includes at least one dielectric layer 116a and metallization patterns 116b in the dielectric layer 116a. In some embodiments, the metallization patterns 116b may comprise pads, vias and/or trace lines to interconnect the through vias 104 and to further connect the through vias 104 to one or more external devices. Although one layer of dielectric layer 116a, and one layer of the metallization patterns 116b is shown in FIG. 1F, it should be noted that the number of layers of the dielectric layer 116a and the metallization patterns 116b is not limited thereto, and this could be adjusted based on requirement.

In some embodiments, the material of the dielectric layer 116a comprises silicon oxide, silicon nitride, silicon carbide, silicon oxynitride, or low-K dielectric materials (such as phosphosilicate glass materials, fluorosilicate glass materials, boro-phosphosilicate glass materials, SiOC, spin-on-glass materials, spin-on-polymers or silicon carbon materials). In some embodiments, the dielectric layer 116a is formed by spin-coating or deposition, including chemical vapor deposition (CVD), plasma-enhanced chemical vapor deposition (PECVD), high-density plasma chemical vapor deposition (HDP-CVD), or the like. In some embodiments, the metallization patterns 116b include under-metal metallurgies (UBMs). In some embodiments, the formation of the metallization patterns 116b may include patterning the dielectric layer using photolithography techniques and one or more etching processes and filling a metallic material into the openings of the patterned dielectric layer. Any excessive conductive material on the dielectric layer may be removed, such as by using a chemical mechanical polishing process. In some embodiments, the material of the metallization patterns 116b includes copper, aluminum, tungsten, silver, and combinations thereof.

As further illustrated in FIG. 5, a plurality of conductive terminals 118 is disposed on the metallization patterns 116b, and are electrically coupled to the through vias 104. In some embodiments, the conductive terminals 118 are placed on the top surface 116s of the redistribution structure 116, and electrically connected to the through vias 104 by the metallization patterns 116b within the package region PKR. In certain embodiments, the conductive terminals 118 are positioned on and physically attached to the metallization patterns 116b. In some embodiments, the conductive terminals 118 include lead-free solder balls, solder balls, ball grid array (BGA) balls, bumps, controlled collapse chip connection (C4) bumps or micro bumps. In some embodiments, the conductive terminals 118 may include a conductive material such as solder, copper, aluminum, gold, nickel, silver, palladium, tin, or a combination thereof. In some embodiments, the conductive terminals 118 are formed by forming the solder paste on the redistribution structure 116 by, for example, evaporation, electroplating, printing or solder transfer and then reflowed into the desired bump shapes. In some embodiments, the conductive terminals 118 are placed on the redistribution structure 116 by ball placement or the like. In other embodiments, the conductive terminals 118 are formed by forming solder-free metal pillars (such as a copper pillar) by sputtering, printing, electroless or electro plating or CVD, and then forming a lead-free cap layer by plating on the metal pillars. The conductive terminals 118 may be used to bond to an external device or an additional electrical component. In some embodiments, the conductive terminals 118 are used to bond to a circuit substrate, a semiconductor substrate or a packaging substrate.

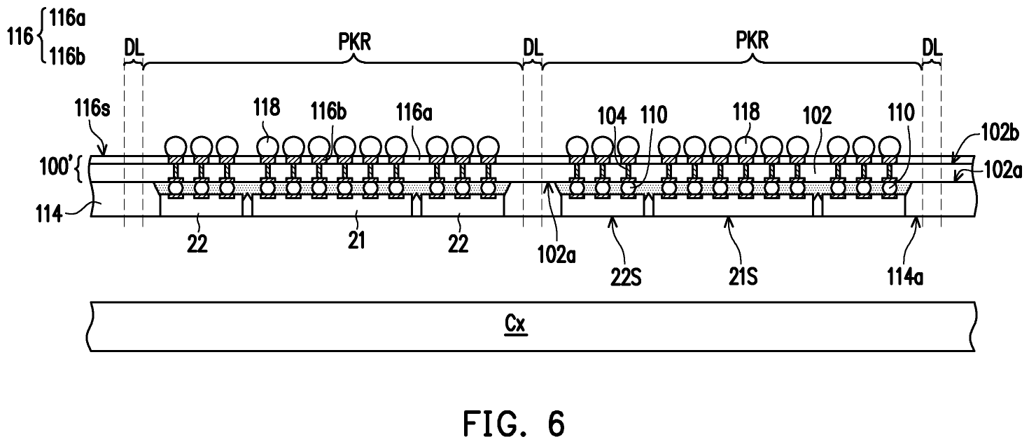

Referring to FIG. 6, after forming the conductive terminals 118, the carrier Cx is de-bonded. For example, the de-bonding process includes projecting a light such as a laser light or an UV light on a debond layer (e.g., light-to-heat-conversion release layer) that is attached to the carrier Cx (not shown), so that the carrier Cx can be easily removed along with the debond layer. In some embodiments, the backside surfaces 21S, 22S of the semiconductor dies 21, 22 are revealed after the de-bonding process.

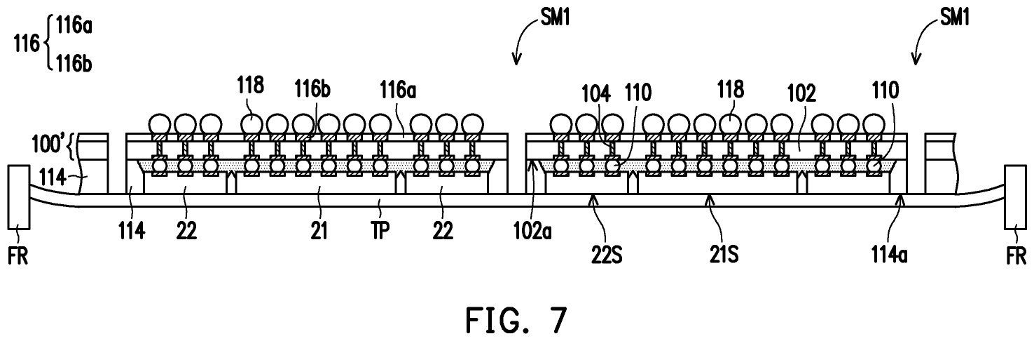

Referring to FIG. 7, in a subsequent step, the structure shown in FIG. 6 is attached to a tape TP (e.g., a dicing tape) supported by a frame FR. Subsequently, the structure shown in FIG. 6 is diced or singulated along the dicing lanes DL to form a plurality of semiconductor packages SM1. For example, the dicing process is performed to cut through the redistribution structure 116, the core portion 102, and the insulating encapsulant 114 to remove portions of the redistribution structure 116, the core portion 102, and the insulating encapsulant 114 along the dicing lanes DL. In some embodiments, the dicing process or the singulation process typically involves dicing with a rotating blade or a laser beam. In other words, the dicing or singulation process is, for example, a laser cutting process, a mechanical sawing process, or other suitable processes.

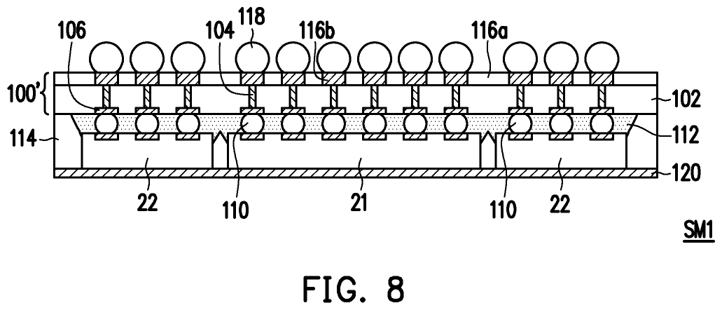

Referring to FIG. 8, after debonding the carrier Cx, the singulated semiconductor package SM1 can be obtained. In some embodiments, a backside metal layer 120 is optionally formed on the backside surfaces 21S, 22S of the semiconductor dies 21, 22. The backside metal layer 120 may also be considered as a part of the semiconductor package SM1. In some embodiments, the backside metal layer 120 may include metal materials, such as aluminum (Al), titanium (Ti), nickel (Ni), vanadium (V), gold (Au), silver (Ag) or copper (Cu). In some embodiments, the backside metal layer 120 is formed by sputtering, electroplating, deposition, or dispensing processes. In certain embodiments, a thickness of the backside metal layer 120 is in a range from about 0.1 μm to about 10 μm. After forming the backside metal layer 120, a semiconductor package SM1 in accordance with some embodiments of the present disclosure is accomplished.

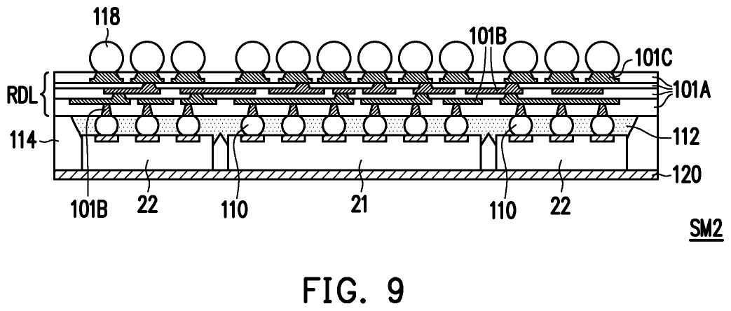

FIG. 9 is a schematic sectional view of a semiconductor package according to some other exemplary embodiments of the present disclosure. The semiconductor package SM2 illustrated in FIG. 2 is similar to the semiconductor package SM illustrated in FIG. 8. Therefore, the same reference numerals may be used to refer to the same or liked parts, and its detailed description will be omitted herein. The difference between the embodiments is that the interposer structure 100′ illustrated in FIG. 8 is replaced with a redistribution layer RDL (or interconnection structure) illustrated in FIG. 9. As illustrated in FIG. 9, the redistribution layer RDL is disposed on the insulating encapsulant 114 and electrically connected to the semiconductor dies 21, 22 through the electrical connectors 110.

In some embodiments, the redistribution layer RDL is formed by sequentially forming one or more dielectric layers 101A and one or more conductive layers 101B in alternation. In certain embodiments, the conductive layers 101B are sandwiched between the dielectric layers 101A, and are electrically and physically connected to the electrical connectors 110. In the exemplary embodiment, the numbers of the dielectric layers 101A and the conductive layers 101B included in the redistribution layer RDL is not limited thereto, and may be designated and selected based on the design requirements. For example, the numbers of the dielectric layers 101A and the conductive layers 101B may be one or more than one.

In some embodiments, the material of the dielectric layers 101A is polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers DII is formed by suitable fabrication techniques such as spin-on coating, chemical vapor deposition (CVD), plasma-enhanced chemical vapor deposition (PECVD) or the like. The disclosure is not limited thereto.

In some embodiments, the material of the conductive layer 101B is made of conductive materials formed by electroplating or deposition, such as aluminum, titanium, copper, nickel, tungsten, and/or alloys thereof, which may be patterned using a photolithography and etching process. In some embodiments, the conductive layer 101B may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In certain embodiments, the redistribution layer RDL further includes a plurality of conductive pads 101C disposed on the conductive layers 101B for electrically connecting with conductive terminals 118. In some embodiments, the materials of the conductive pads 101C may include copper, nickel, titanium, tungsten, or alloys thereof or the like, and may be formed by an electroplating process, for example. The number of conductive pads 101C are not limited in this disclosure, and may be selected based on the design layout. In some embodiments, the conductive pads 101C may be omitted. In other words, the conductive terminals 118 formed in subsequent steps may be directly disposed on the conductive layers 101B of the redistribution layer RDL.

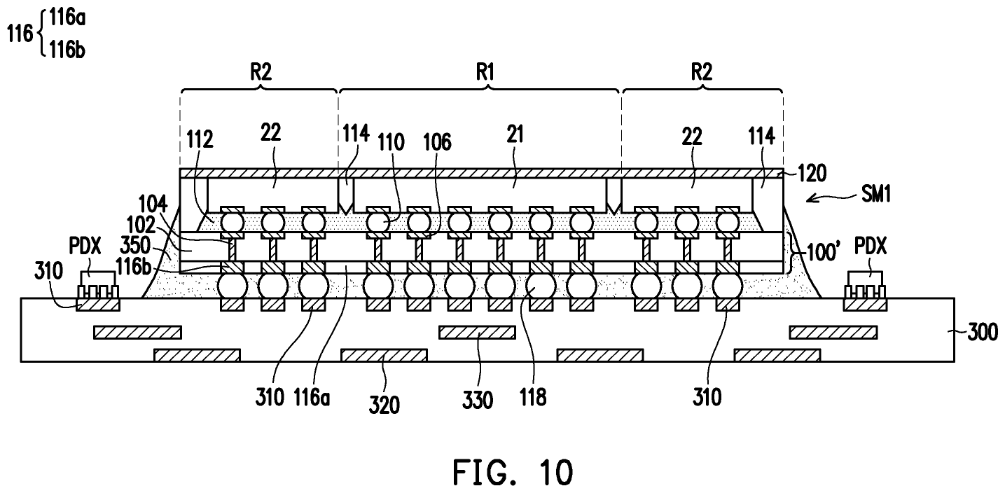

FIG. 10 to FIG. 15 are schematic top and sectional views of various stages in a method of fabricating a package structure according to some exemplary embodiments of the present disclosure. Referring to FIG. 10, in some embodiments, the semiconductor package SM1 obtained in FIG. 8 is mounted or attached onto a circuit substrate 300 through the conductive terminals 118. In some embodiments, the circuit substrate 300 includes contact pads 310, contact pads 320, metallization layers 330, and vias (not shown). In some embodiments, the contact pads 310 and the contact pads 320 are respectively distributed on two opposite sides of the circuit substrate 300, and are exposed for electrically connecting with later-formed elements/features. In some embodiments, the metallization layers 330 and the vias are embedded in the circuit substrate 300 and together provide routing function for the circuit substrate 300, wherein the metallization layers 330 and the vias are electrically connected to the contact pads 310 and the contact pads 320. In other words, at least some of the contact pads 310 are electrically connected to some of the contact pads 320 through the metallization layers 330 and the vias. In some embodiments, the contact pads 310 and the contact pads 320 may include metal pads or metal alloy pads. In some embodiments, the materials of the metallization layers 330 and the vias may be substantially the same or similar to the material of the contact pads 310 and the contact pads 320.

Furthermore, in some embodiments, the semiconductor package SM1 is bonded to the circuit substrate 300 through physically connecting the conductive terminals 118 and the contact pads 310 to form a stacked structure. In some embodiments, the semiconductor package SM1 includes a center region R1 and peripheral regions R2, whereby some of the semiconductor dies 21 are located in the center region R1 and some of the semiconductor dies 22 are located in the peripheral regions R2. In certain embodiments, the semiconductor package SM1 is electrically connected to the circuit substrate 300. In some embodiments, the circuit substrate 300 is such as an organic flexible substrate or a printed circuit board. In some embodiments, the semiconductor package SM1 is bonded to the circuit substrate 300 through physically connecting the conductive terminals 118 and the contact pads 310 of the circuit substrate 300 by a chip on wafer on substrate (CoWoS) packaging processes. In addition, as illustrated in FIG. 10, passive devices PDX (integrated passive device or surface mount devices) may be mounted on the circuit substrate 300. For example, the passive devices PDX may be mounted on the contact pads 310 of the circuit substrate 300 through a soldering process. The disclosure is not limited thereto. In certain embodiments, the passive devices PDX may be mounted on the circuit substrate surrounding the semiconductor package SM1. In some embodiments, the passive devices PDX are omitted.

As further illustrated in FIG. 10, in some embodiments, an underfill structure 350 is formed to fill up the spaces in between the circuit substrate 300 and the semiconductor package SM. In certain embodiments, the underfill structure 350 fills up the spaces in between adjacent conductive terminals 118 and covers the conductive terminals 118. For example, the underfill structure 350 surrounds the plurality of conductive terminals 118. In some embodiments, the passive devices PDX are exposed by the underfill structure 350, and kept a distance apart from the underfill structure 350. In other words, the underfill structure 350 does not cover the passive devices PDX.

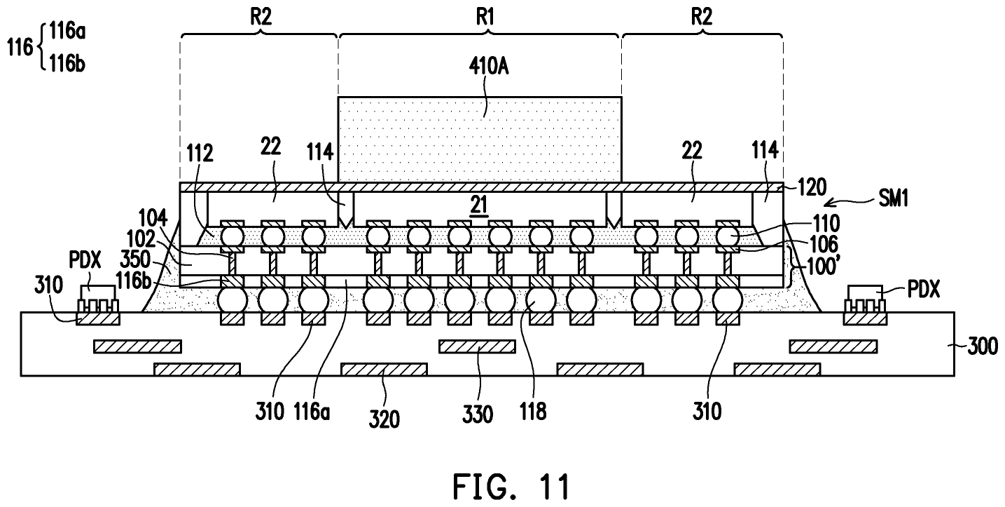

Referring to FIG. 11, in a subsequent step, a first thermal interface material 410A is disposed on the center region R1 over the backside metal layer 120, wherein the first thermal interface material 410A is located outside of the peripheral regions R2. For example, the first thermal interface material 410A is disposed on and overlapped with the semiconductor dies 21. In some embodiments, the first thermal interface material 410A is applied onto the upper surface of the backside metal layer 120 through a pick-and-place (PnP) process. In some embodiments, a flux-material (not shown) may be used to facilitate the attachment between the first thermal interface material 410A and the backside metal layer 120 below. For example, the flux-material is applied to the backside metal layer 120 through a flux jetting process to facilitate soldering, brazing, and/or welding between the semiconductor package SM1 and layers to be formed thereover. In some embodiments, the first thermal interface material 410A is a suitable candidate that help dissipate heat for the semiconductor package SM1. In one exemplary embodiment, the first thermal interface material 410A is indium (In). In some embodiments, the first thermal interface material 410A may have thermal conductivity values higher than about 1 W/(m·K), higher than about 5 W/(m·K), higher than about 10 W/(m·K), or higher.

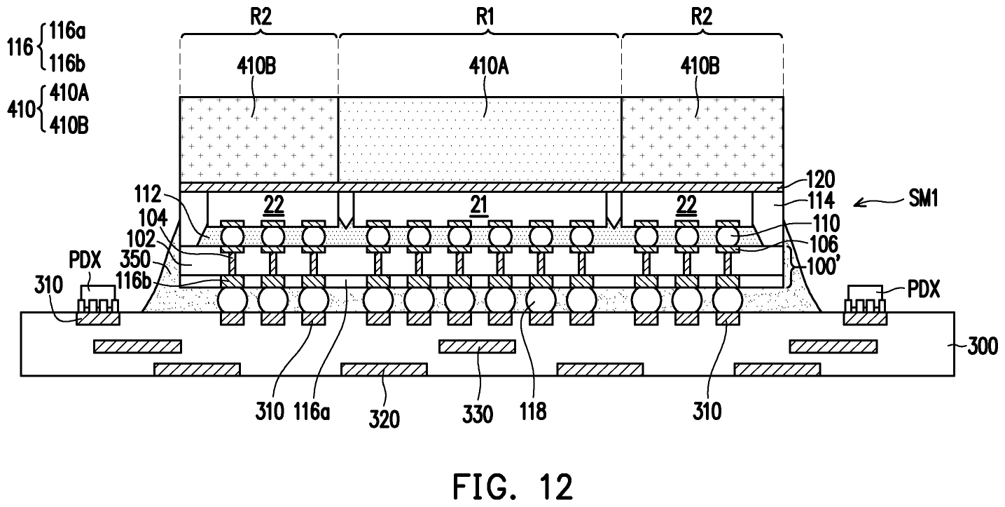

Referring to FIG. 12, in a subsequent step, a second thermal interface material 410B is disposed on the peripheral regions R2 over the backside metal layer 120. For example, the second thermal interface material 410B is disposed aside the first thermal interface material 410A and is in physical contact with the first thermal interface material 410A. In some embodiments, the second thermal interface material 410B is applied onto the upper surface of the backside metal layer 120 through a pick-and-place (PnP) process. In some embodiments, the same flux-material (not shown) described above may be used to facilitate the attachment between the second thermal interface material 410B and the backside metal layer 120 below. In the exemplary embodiment, the first thermal interface material 410A and the second thermal interface material 410B together constitute a thermal interface material structure 410, wherein the first thermal interface material 410A and the second interface material 410B include different materials. In one exemplary embodiment, the second thermal interface material 410B is indium-silver (In10Ag). In some embodiments, the second thermal interface material 410B may have thermal conductivity values higher than about 1 W/(m·K), higher than about 5 W/(m·K), higher than about 10 W/(m·K), or higher.

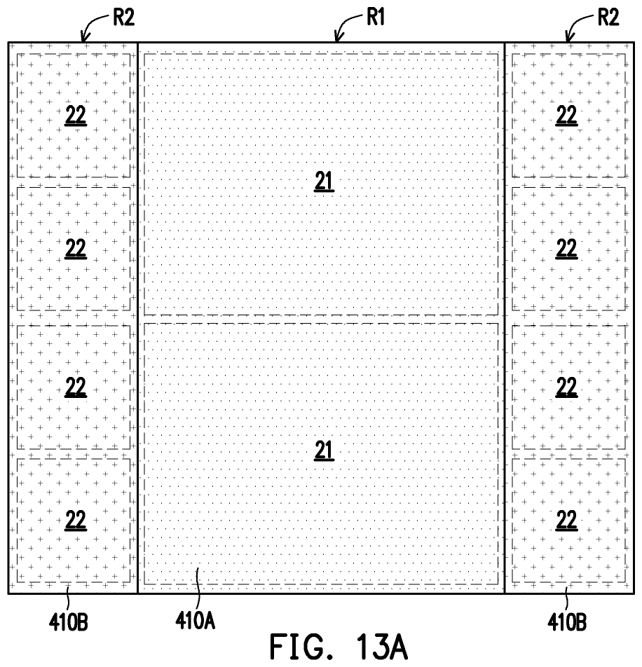

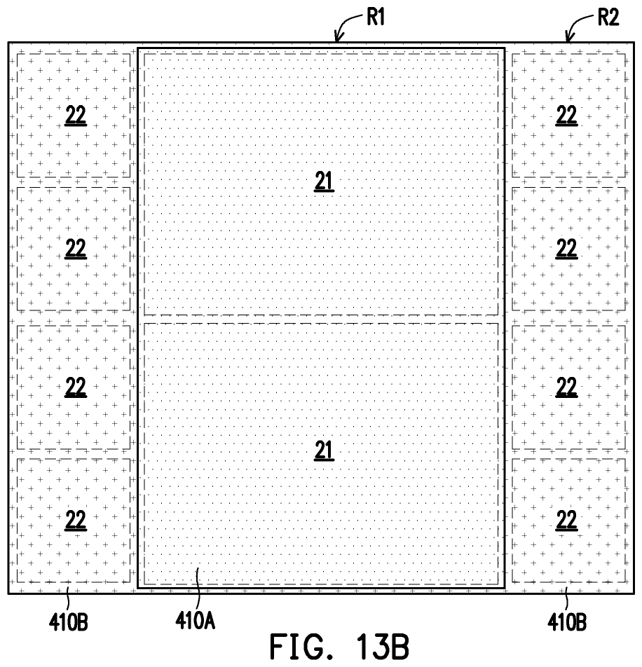

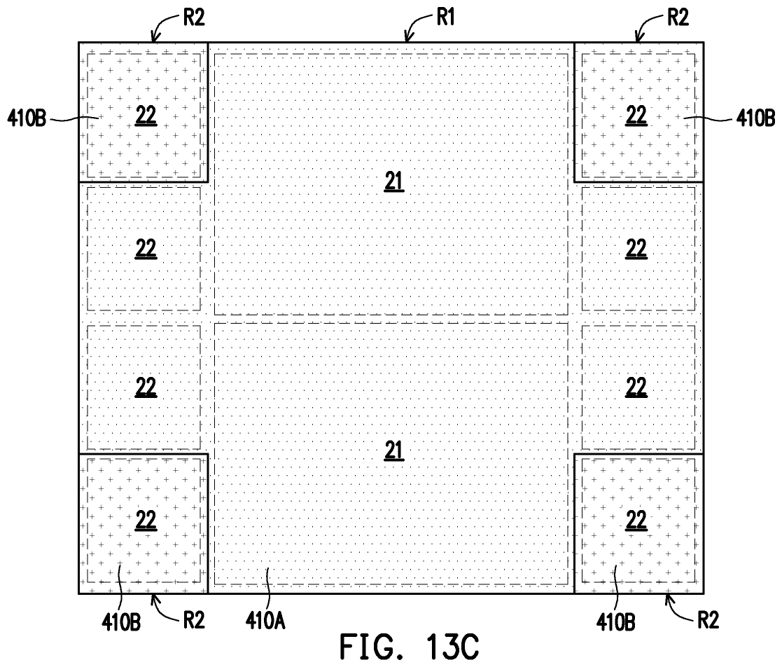

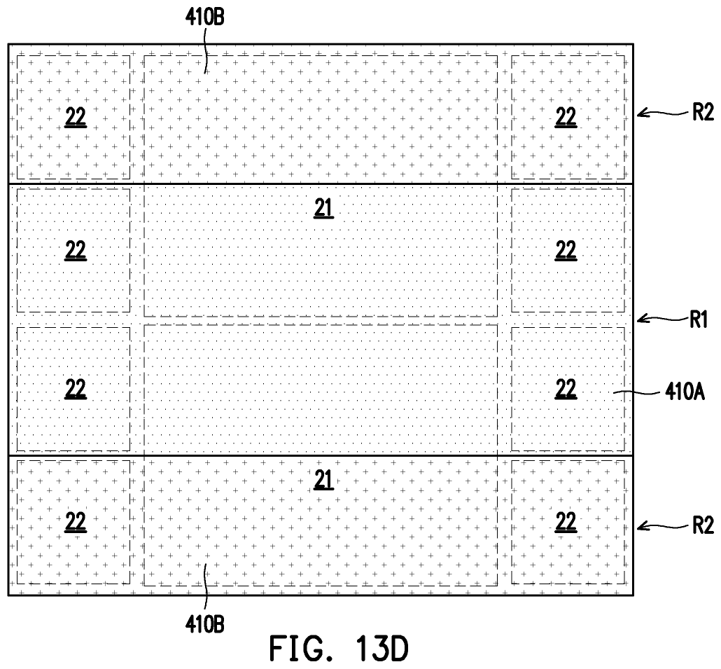

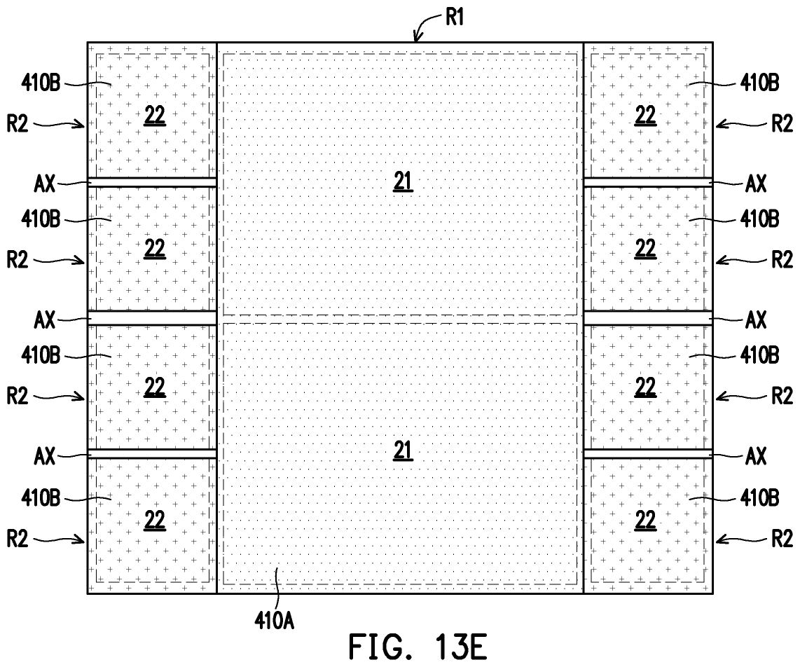

FIG. 13A to FIG. 13E illustrate top views of the different possible arrangements of the first thermal interface material 410A and the second thermal interface material 410B on the semiconductor package SM1 shown in FIG. 12. As shown in FIG. 13A, in one embodiment, the first thermal interface material 410A is disposed on the center region R1 of the semiconductor package SM1, wherein the first thermal interface material 410A covers and overlaps two semiconductor dies 21. In some embodiments, the second thermal interface material 410B is disposed on the peripheral regions R2 of the semiconductor package SM1, and is disposed on two opposing side surfaces of the first thermal interface material 410A. For example, the second thermal interface material 410B covers and overlaps with each of the semiconductor dies 22.

Referring to FIG. 13B, in another embodiment, the first thermal interface material 410A is disposed on the center region R1 of the semiconductor package SM1, wherein the first thermal interface material 410A covers and overlaps two semiconductor dies 21. In some embodiments, an area occupied by the first thermal interface material 410A is substantially equal to an area occupied by the two semiconductor dies 21. For example, one or more side surfaces of the first thermal interface material 410A may be aligned with the side surfaces of the two semiconductor dies 21. Furthermore, the second thermal interface material 410B is disposed on the peripheral regions R2 of the semiconductor package SM1, and is laterally surrounding the first thermal interface material 410A. In certain embodiments, the second thermal interface material 410B covers and overlaps with each of the semiconductor dies 22.

Referring to FIG. 13C, in another embodiment, the first thermal interface material 410A is disposed on the center region R1 of the semiconductor package SM1, wherein the first thermal interface material 410A covers and overlaps two semiconductor dies 21, and covers and overlaps a portion of the semiconductor dies 22. In some embodiments, the second thermal interface material 410B is disposed on the peripheral regions R2 of the semiconductor package SM1, and is disposed on four corners of the first thermal interface material 410A. For example, the second thermal interface material 410B located on four corners of the first thermal interface material 410A, or on four corners of the semiconductor package SM1 are separated from one another by the first thermal interface material 410A. The second thermal interface material 410B disposed on each of the four corners may include a square/rectangular pattern that is respectively covering or overlapped with one semiconductor die 22.

Referring to FIG. 13D, in another embodiment, the first thermal interface material 410A is disposed on the center region R1 of the semiconductor package SM1, wherein the first thermal interface material 410A covers and partially overlaps two semiconductor dies 21, and covers and overlaps a portion of the semiconductor dies 22. In some embodiments, the second thermal interface material 410B is disposed on the peripheral regions R2 of the semiconductor package SM1, and is disposed on two opposing side surfaces of the first thermal interface material 410. For example, the second thermal interface material 410B covers and partially overlaps two semiconductor dies 21, and covers and overlaps another portion of the semiconductor dies 22.

Referring to FIG. 13E, in another embodiment, the first thermal interface material 410A is disposed on the center region R1 of the semiconductor package SM1, wherein the first thermal interface material 410A covers and overlaps two semiconductor dies 21. Furthermore, the second thermal interface material 410B is disposed on the peripheral regions R2 of the semiconductor package SM1, wherein the second thermal interface material 410B includes a plurality of square/rectangular patterns, and each of the square/rectangular patterns is covering or overlapped with one semiconductor die 22. In some embodiments, each of the square/rectangular patterns of the second thermal interface material 410B are separated from one another by air spaces Ax. Furthermore, a side surface of each of the square/rectangular patterns of the second thermal interface material 410B is attached to a side surface of the first thermal interface material 410A.

From the embodiments shown in FIG. 13A to FIG. 13E above, it is noted that the relative positions of the first thermal interface material 410A and the second thermal interface material 410B may be appropriately adjusted as long as the first thermal interface material 410A is disposed in a center region R1 on the semiconductor package SM1, while the second thermal interface material 410B is disposed in peripheral regions R2 on the semiconductor package SM1. In some embodiments, the first thermal interface material 410A is disposed in the center region R1, corresponding to a low warpage exchange region of the semiconductor package SM1. In certain embodiments, the second thermal interface material 410B is disposed in peripheral regions R2 corresponding to a high warpage exchange region of the semiconductor package SM1. Furthermore, the first thermal interface material 410A and the second thermal interface material 410B illustrated in FIG. 12 may be arranged according to any of the embodiments shown in FIG. 13A to FIG. 13E on the semiconductor package SM1.

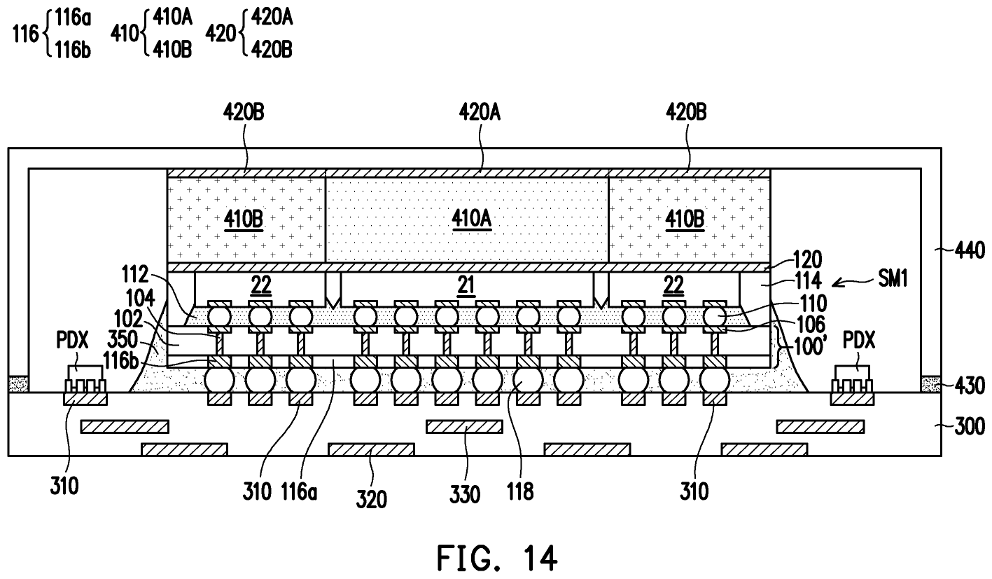

Referring to FIG. 14, after forming the thermal interface material structure 410 including the first thermal interface material 410A and the second thermal interface material 410B, a plating layer 420 is formed over the thermal interface material structure 410, and a lid structure 440 is attached on the circuit substrate 300 through an adhesive 430. In some embodiments, prior to attaching the plating layer 420 on the thermal interface material structure 410, a flux-material is applied to the thermal interface material structure 410 through a flux jetting process to facilitate soldering, brazing, and/or welding between the thermal interface material structure 410 and layers to be formed thereover. In some embodiments, the lid structure 440 along with the plating layer 420 is attached to the thermal interface material structure 410 through the flux-material.

In the exemplary embodiment, the plating layer 420 includes a first plating layer 420A and a second plating layer 420B. For example, the first plating layer 420A is disposed on the first thermal interface material 410A and has a pattern that corresponds to a pattern of the underlying first thermal interface material 410A. Similarly, the second plating layer 420B is disposed on the second thermal interface material 410B and has a pattern that corresponds to a pattern of the underlying second thermal interface material 410B. In other words, the first plating layer 420A is disposed on the thermal interface material structure 410 over the center region R1, while the second plating layer 420B is disposed on the thermal interface material structure 410 over the peripheral regions R2. In the exemplary embodiment, the first plating layer 420A and the second plating layer 420B are made of the same material. For example, the first plating layer 420A and the second plating layer 420B includes plated nickel-gold (Ni—Au).

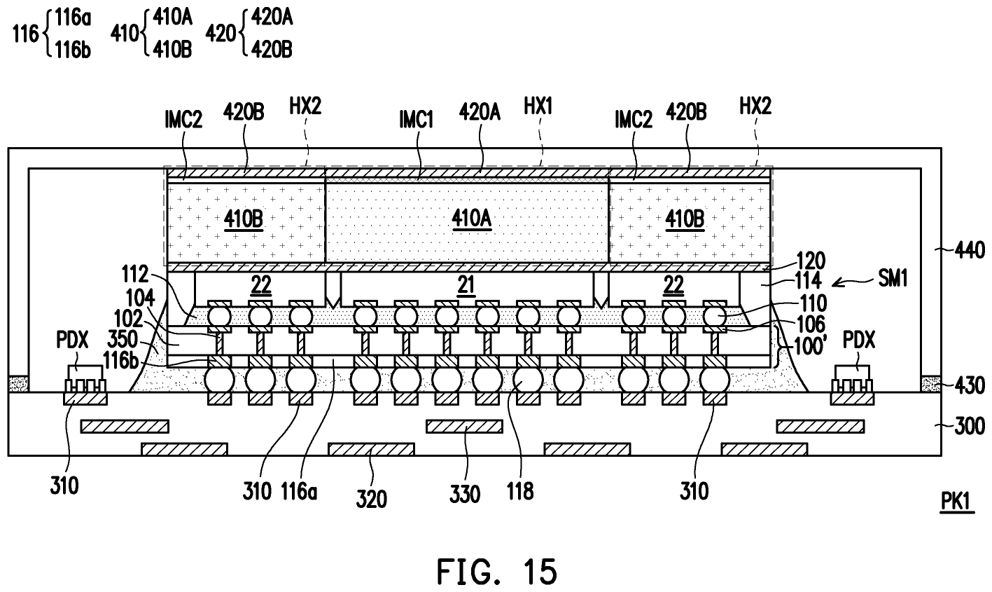

Referring to FIG. 15, after attaching the lid structure 440 along with the plating layer 420 over the thermal interface material structure 410, a heating process (heat clamping process) is performed to secure the plating layer 420 onto the thermal interface material structure 410. For example, after the heating process, a first intermetallic compound IMC1 is formed between the first thermal interface material 410A and the first plating layer 420A in the center region R1, while a second intermetallic compound IMC2 is formed between the second thermal interface material 410B and the second plating layer 420B. For example, the first intermetallic compound IMC1 is formed over the center region R1 of the semiconductor package SM1, while the second thermal interface material 410B is formed over the peripheral regions R2 of the semiconductor package SM1. In some embodiments, the heating process is performed in a temperature range of 100° C. to 200° C.

In some embodiments, a position of the first intermetallic compound IMC1 corresponds to a position of the first thermal interface material 410A, while a position of the formed second intermetallic compound IMC2 corresponds to a position of the second thermal interface material 410B. For example, if the first thermal interface material 410A and the second thermal interface material 410B are arranged in a way shown in FIG. 13A or FIG. 13D, then the second intermetallic compound IMC2 may also be formed on two opposing side surfaces of the first intermetallic compound IMC1. On the other hand, if the first thermal interface material 410A and the second thermal interface material 410B are arranged in a way shown in FIG. 13C, then the second intermetallic compound IMC2 may be formed on four corners of the first intermetallic compound IMC1.

In the exemplary embodiment, the first thermal interface material 410A is indium (In) and the second thermal interface material 410B is (In10Ag), while the first plating layer 420A and the second plating layer 420B includes plated nickel-gold (Ni—Au). Under such circumstances, the first intermetallic compound IMC1 formed between the first thermal interface material 410A and the first plating layer 420A will include at least one selected from the group consisting of AuIn2 and Ni—Au—In, and the second intermetallic compound IMC1 formed between the second thermal interface material 410B and the second plating layer 420B will include at least one selected from the group consisting of AgIn, AuIn2, Ni—Ag—In and Ni—Au—In. In one embodiment, the first intermetallic compound IMC1 includes at least AuIn2, whereas the second intermetallic compound includes at least Ni—Ag—In. In some embodiments, the first intermetallic compound IMC1 and the second intermetallic compound IMC2 comprises different materials.

As further illustrated in FIG. 15, after forming the first intermetallic compound IMC1 and the second intermetallic compound IMC2, a plurality of conductive terminals 340 are respectively formed on the circuit substrate 300. For example, the conductive terminals 340 are connected to and joined with the contact pads 320 of the circuit substrate 300 through a reflow process. In other words, the conductive terminals 340 are electrically connected to the circuit substrate 300 through the contact pads 320. Through the contact pads 310 and the contact pads 320, some of the conductive terminals 340 are electrically connected to the semiconductor package SM1 (e.g. the semiconductor dies 21 and 22 included therein). In some embodiments, the conductive terminals 340 are, for example, solder balls or ball grid array (BGA) balls.

After forming the conductive terminals 340 on the circuit substrate 300, a package structure PK1 in accordance with some embodiments of the present disclosure is accomplished. In the package structure PK1, a first heat dissipation component HX1 and a second heat dissipation component HX2 are formed on the semiconductor package SM1 for providing improved heat dissipation. In the exemplary embodiment, the first heat dissipation component HX1 includes the first thermal interface material 410A, the first intermetallic compound IMC1 and the first plating layer 420A, while the second heat dissipation component HX2 includes the second thermal interface material 410B, the second intermetallic compound IMC2 and the second plating layer 420B. In the exemplary embodiment, since the first heat dissipation component HX1 is disposed in a center region R1, and the second heat dissipation component HX2 is disposed in the peripheral regions R2 over the semiconductor package SM1, and the first heat dissipation component HX1 and the second heat dissipation component HX2 includes mixed thermal interface materials (410A, 410B), thus, a material loss of the thermal interface material structure 410 is minimized during the reflow process of joining the conductive terminals 340 to the circuit substrate 300. Overall, by using different thermal dissipation material components on different areas of the semiconductor package SM1, the obtained package structure PK1 can have improved reliability and thermal dissipation performance.

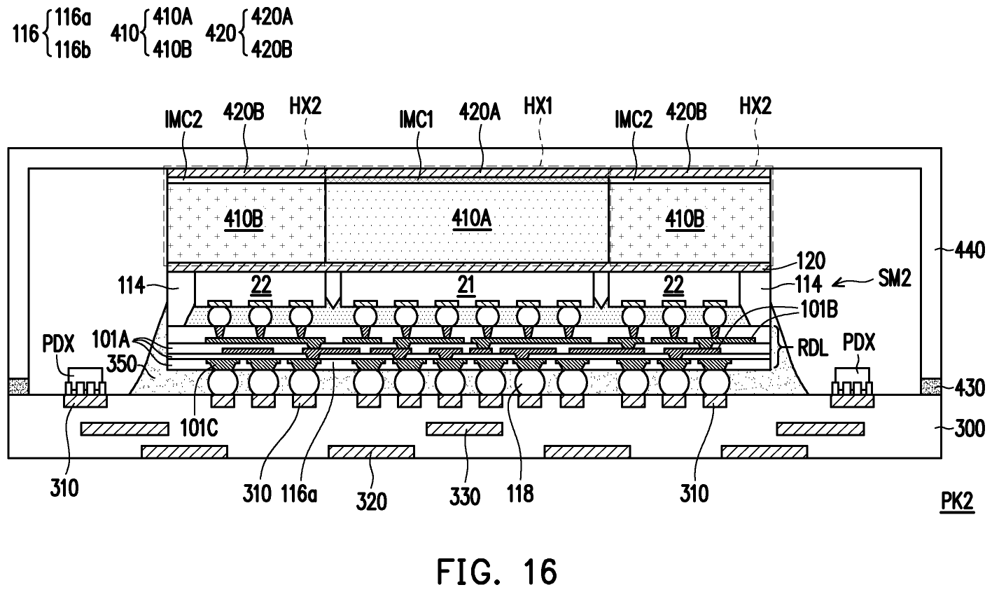

FIG. 16 is a schematic sectional view of a package structure according to some other exemplary embodiments of the present disclosure. The package structure PK2 illustrated in FIG. 16 is similar to the package structure PK1 illustrated in FIG. 15. Therefore, the same reference numerals are used to refer to the same or liked parts, and its detailed description will be omitted herein. The difference between the embodiments is that the semiconductor package SM2 in FIG. 16 is used in replacement of the semiconductor package SM1 in FIG. 15. The details of the semiconductor package SM2 may be referred to the descriptions of FIG. 9, thus will not be repeated herein. As illustrated in FIG. 16, in the exemplary embodiment, since the first heat dissipation component HX1 is disposed in a center region R1, and the second heat dissipation component HX2 is disposed in the peripheral regions R2 over the semiconductor package SM1, and the first heat dissipation component HX1 and the second heat dissipation component HX2 includes mixed thermal interface materials (410A, 410B), thus, a material loss of the thermal interface material structure 410 is minimized during the reflow process of joining the conductive terminals 340 to the circuit substrate 300. Overall, by using different thermal dissipation material components on different areas of the semiconductor package SM2, the obtained package structure PK2 can have improved reliability and thermal dissipation performance.

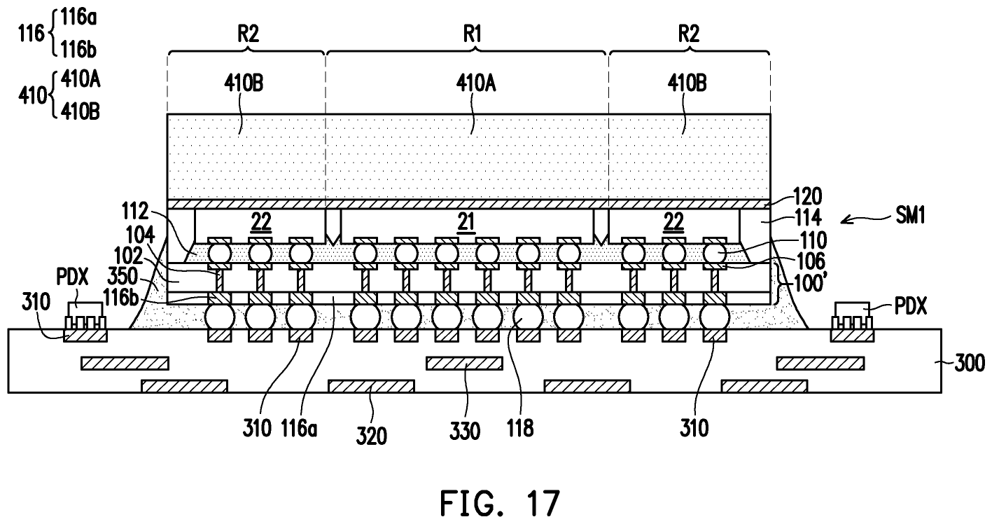

FIG. 17 to FIG. 20 are schematic top and sectional views of various stages in a method of fabricating a package structure according to some other exemplary embodiments of the present disclosure. The method illustrated in FIG. 17 to FIG. 20 is similar to the method illustrated in FIG. 1A to FIG. 15. Therefore, the same reference numerals are used to refer to the same or liked parts, and its detailed description will be omitted herein. Referring to FIG. 17, the same steps as illustrated in FIG. 1A to FIG. 10 are performed to form the semiconductor package SM1 on the circuit substrate 300. Thereafter, a thermal interface material structure 410 is disposed on the center region R1 and on the peripheral regions R2 of the semiconductor package SM1 over the backside metal layer 120 through a pick-and-place (PnP) process. For example, a first thermal interface material 410A is disposed on the center region R1 and overlapped with the semiconductor dies 21, while a second thermal interface material 410B is disposed on the peripheral regions R2 and overlapped with the semiconductor dies 22. In some embodiments, a flux-material (not shown) may be used to facilitate the attachment between the first thermal interface material 410A, the second thermal interface material 410B and the backside metal layer 120 below.

In some embodiments, both the first thermal interface material 410A and the second thermal interface material 410B are made of the same material. For example, the first thermal interface material 410A and the second thermal interface material 410B are made of indium (In). In some embodiments, the first thermal interface material 410A and the second thermal interface material 410B may have thermal conductivity values higher than about 1 W/(m·K), higher than about 5 W/(m·K), higher than about 10 W/(m·K), or higher.

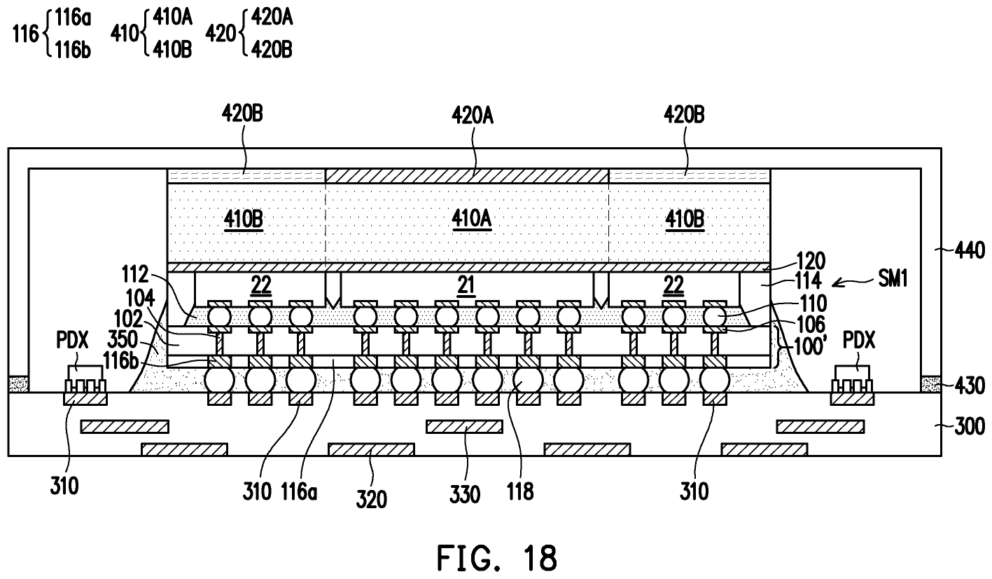

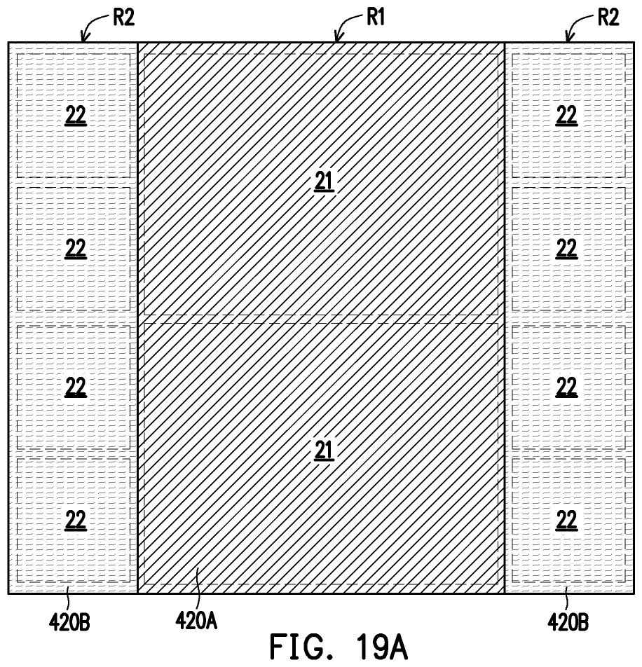

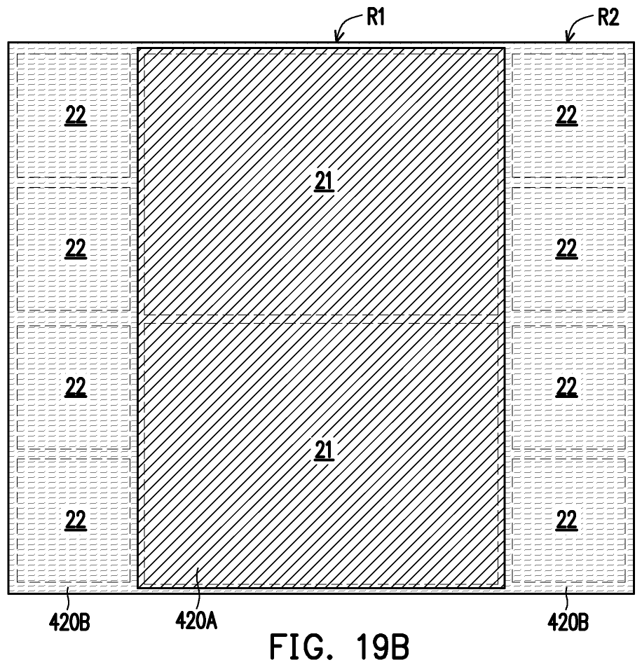

Referring to FIG. 18, after forming the thermal interface material structure 410 including the first thermal interface material 410A and the second thermal interface material 410B, a plating layer 420 is formed over the thermal interface material structure 410, and a lid structure 440 is attached on the circuit substrate 300 through an adhesive 430. In some embodiments, prior to attaching the plating layer 420 on the thermal interface material structure 410, a flux-material is applied to the thermal interface material structure 410 through a flux jetting process to facilitate soldering, brazing, and/or welding between the thermal interface material structure 410 and layers to be formed thereover. In some embodiments, the lid structure 440 along with the plating layer 420 is attached to the thermal interface material structure 410 through the flux-material.

In the exemplary embodiment, the plating layer 420 includes a first plating layer 420A and a second plating layer 420B. For example, the first plating layer 420A is disposed on the thermal interface material structure 410 over the center region R1, while the second plating layer 420B is disposed on the thermal interface material structure 410 over the peripheral regions R2. In the exemplary embodiment, the first plating layer 420A and the second plating layer 420B are made of different materials. For example, the first plating layer 420A includes plated nickel-gold (Ni—Au), and the second plating layer 420B includes plated nickel-silver (Ni—Ag).

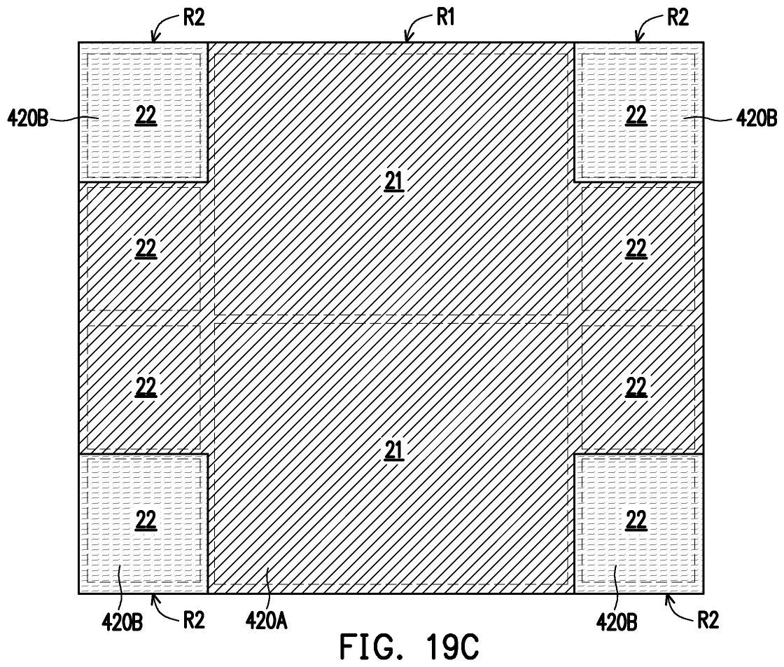

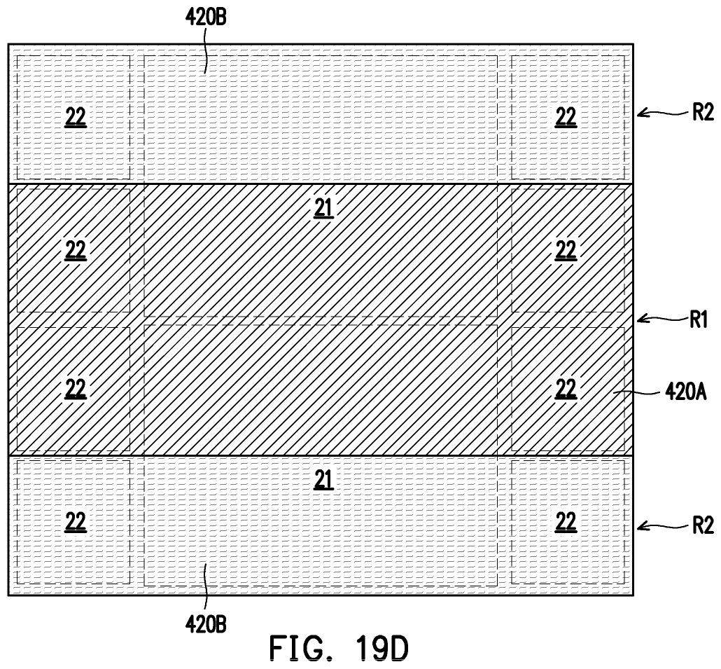

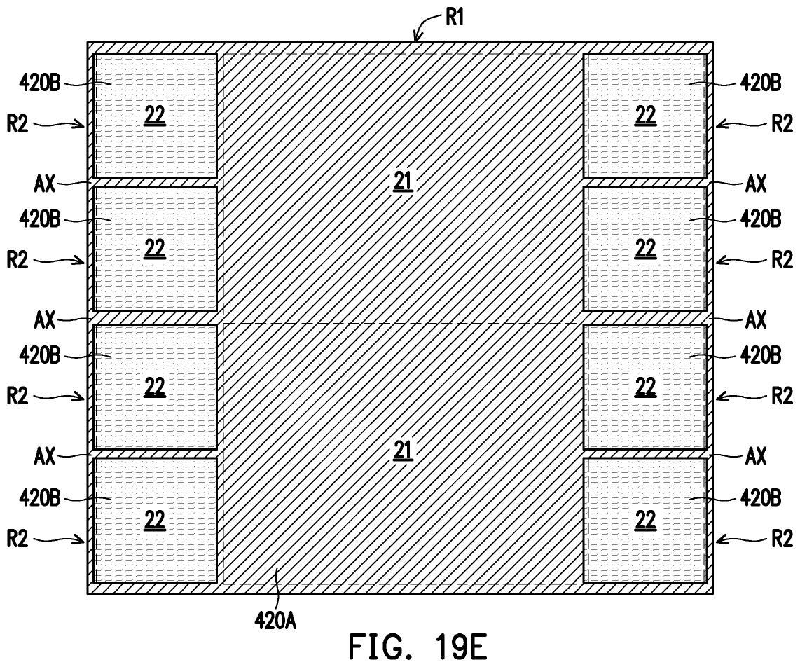

FIG. 19A to FIG. 19E illustrate top views of the different possible arrangements of the first plating layer 420A and the second plating layer 420B on the thermal interface material structure 410 shown in FIG. 18. As shown in FIG. 19A, in one embodiment, the first plating layer 420A is disposed on the first thermal interface material 410A, over the center region R1 of the semiconductor package SM1. For example, the first plating layer 420A covers and overlaps two semiconductor dies 21. In some embodiments, the second plating layer 420B is disposed on the second thermal interface material 410B over the peripheral regions R2 of the semiconductor package SM1, and is disposed on two opposing side surfaces of the first plating layer 420A. For example, the second plating layer 420B covers and overlaps with each of the semiconductor dies 22.

Referring to FIG. 19B, in another embodiment, the first plating layer 420A is disposed on the first thermal interface material 410A, over the center region R1 of the semiconductor package SM1, wherein the first plating layer 420A covers and overlaps two semiconductor dies 21. In some embodiments, an area occupied by the first plating layer 420A is substantially equal to an area occupied by the two semiconductor dies 21. For example, one or more side surfaces of the first plating layer 420A may be aligned with the side surfaces of the two semiconductor dies 21. Furthermore, the second plating layer 420B is disposed on the second thermal interface material 410B over the peripheral regions R2 of the semiconductor package SM1, and is laterally surrounding the first plating layer 420A. In some embodiments, the second plating layer 420B B covers and overlaps with each of the semiconductor dies 22.

Referring to FIG. 19C, in another embodiment, the first plating layer 420A is disposed on the first thermal interface material 410A, over the center region R1 of the semiconductor package SM1, wherein the first plating layer 420A covers and overlaps two semiconductor dies 21, and covers and overlaps a portion of the semiconductor dies 22. In some embodiments, the second plating layer 420B is disposed on the second thermal interface material 410B over the peripheral regions R2 of the semiconductor package SM1, and is disposed on four corners of the first plating layer 420A. For example, the second plating layer 420B located on four corners of the first plating layer 420A, or on four corners of the semiconductor package SM1 are separated from one another by the first plating layer 420A. The second plating layer 420B disposed on each of the four corners may include a square/rectangular pattern that is respectively covering or overlapped with one semiconductor die 22.

Referring to FIG. 19D, in another embodiment, the first plating layer 420A is disposed on the first thermal interface material 410A, over the center region R1 of the semiconductor package SM1, wherein the first plating layer 420A covers and partially overlaps two semiconductor dies 21, and covers and overlaps a portion of the semiconductor dies 22. In some embodiments, the second plating layer 420B is disposed on the second thermal interface material 410B over the peripheral regions R2 of the semiconductor package SM1, and is disposed on two opposing side surfaces of the first plating layer 420A. For example, the second plating layer 420B covers and partially overlaps two semiconductor dies 21, and covers and overlaps another portion of the semiconductor dies 22.

Referring to FIG. 19E, in another embodiment, the first plating layer 420A is disposed on the first thermal interface material 410A, over the center region R1 of the semiconductor package SM1, wherein the first plating layer 420A covers and overlaps two semiconductor dies 21. In some embodiments, the second plating layer 420B is disposed on the second thermal interface material 410B over the peripheral regions R2 of the semiconductor package SM1, wherein the second plating layer 420B includes a plurality of square/rectangular patterns, and each of the square/rectangular patterns is covering or overlapped with one semiconductor die 22. In some embodiments, each of the square/rectangular patterns of the second plating layer 420B are separated from one another by the first plating layer 420A. In other words, the first plating layer 420A is laterally surrounding each of the square/rectangular patterns of the second plating layer 420B.

From the embodiments shown in FIG. 19A to FIG. 19E above, it is noted that the relative positions of the first plating layer 420A and the second plating layer 420B may be appropriately adjusted as long as the first plating layer 420A is disposed in a center region R1 on the semiconductor package SM1, while the second plating layer 420B is disposed in peripheral regions R2 on the semiconductor package SM1. In some embodiments, the first plating layer 420A is disposed in the center region R1, corresponding to a low warpage exchange region of the semiconductor package SM1. In certain embodiments, the second plating layer 420B is disposed in peripheral regions R2 corresponding to a high warpage exchange region of the semiconductor package SM1. Furthermore, the first plating layer 420A and the second plating layer 420B illustrated in FIG. 18 may be arranged according to any of the embodiments shown in FIG. 19A to FIG. 19E on the thermal interface material structure 410 over the semiconductor package SM1.

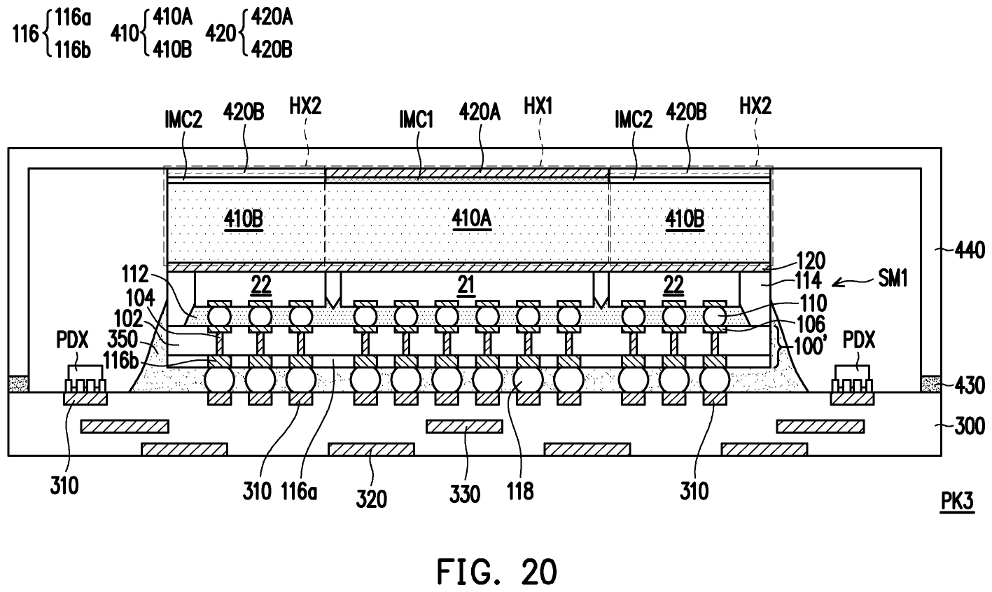

Referring to FIG. 20, after attaching the lid structure 440 along with the plating layer 420 over the thermal interface material structure 410, a heating process (heat clamping process) is performed to secure the plating layer 420 onto the thermal interface material structure 410. For example, after the heating process, a first intermetallic compound IMC1 is formed between the first thermal interface material 410A and the first plating layer 420A in the center region R1, while a second intermetallic compound IMC2 is formed between the second thermal interface material 410B and the second plating layer 420B. For example, the first intermetallic compound IMC1 is formed over the center region R1 of the semiconductor package SM1, while the second thermal interface material 410B is formed over the peripheral regions R2 of the semiconductor package SM1. In some embodiments, the heating process is performed in a temperature range of 100° C. to 200° C.

In the exemplary embodiment, the first thermal interface material 410A and the second thermal interface material 410B are indium (In), while first plating layer 420A includes plated nickel-gold (Ni—Au), and the second plating layer 420B includes plated nickel-silver (Ni—Ag). Under such circumstances, the first intermetallic compound IMC1 formed between the first thermal interface material 410A and the first plating layer 420A will include at least one selected from the group consisting of AuIn2 and Ni—Au—In, and the second intermetallic compound IMC1 formed between the second thermal interface material 410B and the second plating layer 420B will include at least one selected from the group consisting of AgIn and Ni—Ag—In. In other words, the first intermetallic compound IMC1 and the second intermetallic compound IMC2 comprises different materials.

As further illustrated in FIG. 20, after forming the first intermetallic compound IMC1 and the second intermetallic compound IMC2, a plurality of conductive terminals 340 are respectively formed on the circuit substrate 300. In some embodiments, the conductive terminals 340 are, for example, solder balls or ball grid array (BGA) balls. After forming the conductive terminals 340 on the circuit substrate 300, a package structure PK3 in accordance with some embodiments of the present disclosure is accomplished.

In the package structure PK3, a first heat dissipation component HX1 and a second heat dissipation component HX2 are formed on the semiconductor package SM1 for providing improved heat dissipation. In the exemplary embodiment, the first heat dissipation component HX1 includes the first thermal interface material 410A, the first intermetallic compound IMC1 and the first plating layer 420A, while the second heat dissipation component HX2 includes the second thermal interface material 410B, the second intermetallic compound IMC2 and the second plating layer 420B. In the exemplary embodiment, since the first heat dissipation component HX1 is disposed in a center region R1, and the second heat dissipation component HX2 is disposed in the peripheral regions R2 over the semiconductor package SM1, and the first heat dissipation component HX1 and the second heat dissipation component HX2 includes mixed plating layer materials (420A, 420B), thus, the mixed plating layer materials (420A, 420B) may react with different regions of the thermal interface material structure 410 to form intermetallic compounds (IMC1, IMC2) having different thermal properties. As such, a material loss of the thermal interface material structure 410 is minimized during the reflow process of joining the conductive terminals 340 to the circuit substrate 300. Overall, by using different thermal dissipation material components on different areas of the semiconductor package SM1, the obtained package structure PK3 can have improved reliability and thermal dissipation performance.

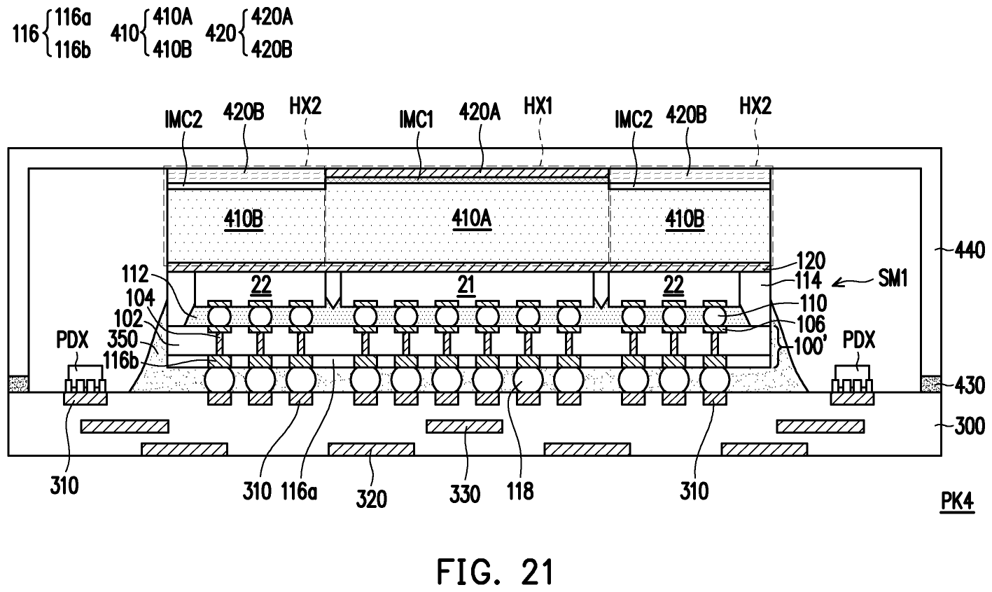

FIG. 21 is a schematic sectional view of a package structure according to some other exemplary embodiments of the present disclosure. The package structure PK4 illustrated in FIG. 21 is similar to the package structure PK3 illustrated in FIG. 20. Therefore, the same reference numerals are used to refer to the same or liked parts, and its detailed description will be omitted herein. The difference between the embodiments is in the design of the thermal interface material structure 410 and the plating layer 420. In the embodiment shown in FIG. 20, the first plating layer 420A and the second plating layer 420B are shown to have the same thickness. However, the disclosure is not limited thereto. As illustrated in FIG. 21, the first plating layer 420A and the second plating layer 420B have different thicknesses. For example, the second plating layer 420B is formed with a thickness greater than the first plating layer 420B. In such embodiment, the first intermetallic compound IMC1 is formed to be misaligned with the second intermetallic compound IMC2. Furthermore, the first thermal interface material 410A may have a thickness greater than the second thermal interface material 410B.

In the package structure PK4 illustrated in FIG. 21, since the first heat dissipation component HX1 is disposed in a center region R1, and the second heat dissipation component HX2 is disposed in the peripheral regions R2 over the semiconductor package SM1, and the first heat dissipation component HX1 and the second heat dissipation component HX2 includes mixed plating layer materials (420A, 420B), thus, the mixed plating layer materials (420A, 420B) may react with different regions of the thermal interface material structure 410 to form intermetallic compounds (IMC1, IMC2) having different thermal properties. As such, a material loss of the thermal interface material structure 410 is minimized during the reflow process of joining the conductive terminals 340 to the circuit substrate 300. Overall, by using different thermal dissipation material components on different areas of the semiconductor package SM1, the obtained package structure PK4 can have improved reliability and thermal dissipation performance.

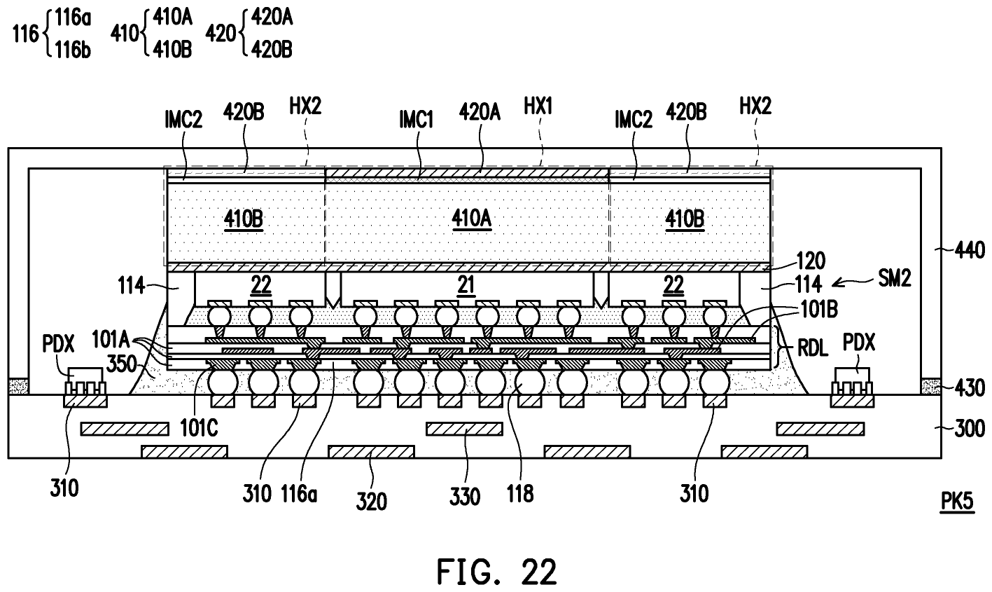

FIG. 22 is a schematic sectional view of a package structure according to some other exemplary embodiments of the present disclosure. The package structure PK5 illustrated in FIG. 22 is similar to the package structure PK3 illustrated in FIG. 20. Therefore, the same reference numerals are used to refer to the same or liked parts, and its detailed description will be omitted herein. The difference between the embodiments is that the semiconductor package SM2 in FIG. 22 is used in replacement of the semiconductor package SM1 in FIG. 20. The details of the semiconductor package SM2 may be referred to the descriptions of FIG. 9, thus will not be repeated herein. As illustrated in FIG. 22, in the exemplary embodiment, since the first heat dissipation component HX1 is disposed in a center region R1, and the second heat dissipation component HX2 is disposed in the peripheral regions R2 over the semiconductor package SM1, and the first heat dissipation component HX1 and the second heat dissipation component HX2 includes mixed thermal interface materials (410A, 410B), thus, a material loss of the thermal interface material structure 410 is minimized during the reflow process of joining the conductive terminals 340 to the circuit substrate 300. Overall, by using different thermal dissipation material components on different areas of the semiconductor package SM2, the obtained package structure PK5 can have improved reliability and thermal dissipation performance.

In the above-mentioned embodiments, a first heat dissipation component and a second heat dissipation component are disposed on backside surfaces of the semiconductor package. Since the first heat dissipation component and the second heat dissipation component includes different thermal interface materials or different plating layer materials, a material loss of the thermal interface material structure in different regions over the semiconductor package is minimized during a reflow process in forming the package structure. As such, with the flexible thermal characteristics of different thermal dissipation material components on different areas of the semiconductor package, the obtained package structure can have improved reliability and thermal dissipation performance.

In accordance with some embodiments of the present disclosure, a package structure includes a circuit substrate, a semiconductor package, a thermal interface material structure, a plating layer, a first intermetallic compound, a second intermetallic compound and a lid structure. The semiconductor package is disposed on and electrically connected to the circuit substrate, wherein the semiconductor package comprises a center region and peripheral regions. The thermal interface material structure is disposed on the center region and on the peripheral regions of the semiconductor package. The plating layer is disposed on the thermal interface material structure. The first intermetallic compound is formed in between the thermal interface material structure and the plating layer over the center region of the semiconductor package. The second intermetallic compound is formed in between the thermal interface material structure and the plating layer over the peripheral regions of the semiconductor package, wherein the second intermetallic compound is different from the first intermetallic compound. The lid structure is disposed on the circuit substrate and covering the semiconductor package.

In accordance with some other embodiments of the present disclosure, a package structure includes an interconnection structure, a plurality of first semiconductor dies, a plurality of second semiconductor dies, a first heat dissipation component, a second heat dissipation component, and a lid structure. The first semiconductor dies are disposed on a center region of the interconnection structure and electrically connected to the interconnection structure. The second semiconductor dies are disposed on peripheral regions of the interconnection structure and electrically connected to the interconnection structure. The first heat dissipation component is disposed on and covering backside surfaces of the plurality of first semiconductor dies. The second heat dissipation component is disposed on and covering backside surfaces of the plurality of second semiconductor dies, wherein the first heat dissipation component and the second heat dissipation component comprises different materials. The lid structure is disposed on and in contact with the first heat dissipation component and the second heat dissipation component, and laterally surrounding the first heat dissipation component, the second heat dissipation component, the plurality of first semiconductor dies, the plurality of second semiconductor dies and the interconnection structure.

In accordance with yet another embodiment of the present disclosure, a method of fabricating a package structure is described. The method includes the following steps. A semiconductor package is disposed on a circuit substrate, wherein the semiconductor package comprises a center region and peripheral regions. A thermal interface material structure is formed on the center region and on the peripheral regions of the semiconductor package. A plating layer is disposed on the thermal interface material structure, and a lid structure is disposed on the circuit substrate, wherein the lid structure is contacting the plating layer and covering the semiconductor package. A heating process is performed for forming a first intermetallic compound in between the thermal interface material structure and the plating layer over the center region of the semiconductor package, and forming a second intermetallic compound in between the thermal interface material structure and the plating layer over the peripheral regions of the semiconductor package, wherein the second intermetallic compound is different from the first intermetallic compound.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a circuit substrate;
a semiconductor package disposed on and electrically connected to the circuit substrate, wherein the semiconductor package comprises a center region and peripheral regions;
a thermal interface material structure disposed on the center region and on the peripheral regions of the semiconductor package;
a plating layer disposed on the thermal interface material structure;
a first intermetallic compound formed in between the thermal interface material structure and the plating layer over the center region of the semiconductor package;
a second intermetallic compound formed in between the thermal interface material structure and the plating layer over the peripheral regions of the semiconductor package, wherein the second intermetallic compound is different from the first intermetallic compound; and
a lid structure disposed on the circuit substrate and covering the semiconductor package.

2. The package structure according to claim 1, wherein the thermal interface material structure comprises a first thermal interface material disposed on the center region, and a second thermal interface material different from the first thermal interface material and disposed on the peripheral regions.

3. The package structure according to claim 2, wherein the first thermal interface material is indium (In) and the second thermal interface material is indium silver (In10Ag).

4. The package structure according to claim 1, wherein the plating layer comprises a first plating layer disposed on the thermal interface material structure over the center region, and a second plating layer different from the first plating layer and disposed on the thermal interface material structure over the peripheral regions.

5. The package structure according to claim 4, wherein a thickness of the first plating layer is different from a thickness of the second plating layer.

6. The package structure according to claim 4, wherein the first plating layer includes plated nickel-gold (Ni—Au), and the second plating layer includes plated nickel-silver (Ni—Ag).

7. The package structure according to claim 1, wherein the second intermetallic compound is formed on two opposing side surfaces of the first intermetallic compound.

8. The package structure according to claim 1, wherein the second intermetallic compound is formed on four corners of the first intermetallic compound.

9. A package structure, comprising:
an interconnection structure;
a plurality of first semiconductor dies disposed on a center region of the interconnection structure and electrically connected to the interconnection structure;
a plurality of second semiconductor dies disposed on peripheral regions of the interconnection structure and electrically connected to the interconnection structure;
a first heat dissipation component disposed on and covering backside surfaces of the plurality of first semiconductor dies;
a second heat dissipation component disposed on and covering backside surfaces of the plurality of second semiconductor dies, wherein the first heat dissipation component and the second heat dissipation component comprises different materials; and
a lid structure disposed on and in contact with the first heat dissipation component and the second heat dissipation component, and laterally surrounding the first heat dissipation component, the second heat dissipation component, the plurality of first semiconductor dies, the plurality of second semiconductor dies and the interconnection structure.

10. The package structure according to claim 9, wherein
the first heat dissipation component comprises a first thermal interface material, and a first plating layer disposed on the first thermal interface material; and
the second heat dissipation component comprises a second thermal interface material, and a second plating layer disposed on the second thermal interface material, wherein the second thermal interface material and the first thermal interface material include different materials or the second plating layer and the first plating layer include different materials.

11. The package structure according to claim 10, wherein the first thermal interface material is indium (In), the second thermal interface material is indium-silver (In10Ag), and the first plating layer and the second plating layer includes plated nickel-gold (Ni—Au).

12. The package structure according to claim 10, wherein the first thermal interface material and the second thermal interface material are indium (In), the first plating layer includes plated nickel-gold (Ni—Au), and the second plating layer includes plated nickel-silver (Ni—Ag).

13. The package structure according to claim 12, wherein the first plating layer and the second plating layer have different thicknesses.

14. The package structure according to claim 10, further comprising first intermetallic compounds formed between the first thermal interface material and the first plating layer and second intermetallic compounds formed between the second thermal interface and the second plating layer.

15. The package structure according to claim 14, wherein the first intermetallic compounds comprise at least one selected from the group consisting of AuIn2 and Ni—Au—In, and the second intermetallic compounds comprise at least one selected from the group consisting of AgIn, AuIn2, Ni—Ag—In and Ni—Au—In.

16. A method of fabricating a package structure, comprising:
disposing a semiconductor package on a circuit substrate, wherein the semiconductor package comprises a center region and peripheral regions;
forming a thermal interface material structure on the center region and on the peripheral regions of the semiconductor package;
disposing a plating layer on the thermal interface material structure and a lid structure on the circuit substrate, wherein the lid structure is contacting the plating layer and covering the semiconductor package; and
performing a heating process for forming a first intermetallic compound in between the thermal interface material structure and the plating layer over the center region of the semiconductor package, and forming a second intermetallic compound in between the thermal interface material structure and the plating layer over the peripheral regions of the semiconductor package, wherein the second intermetallic compound is different from the first intermetallic compound.

17. The method according to claim 16, wherein forming the thermal interface material structure comprises forming a first thermal interface material on the center region, and forming a second thermal interface material different from the first thermal interface material on the peripheral regions.

18. The method according to claim 17, wherein the first thermal interface material is indium (In) and the second thermal interface material is indium silver (In10Ag).

19. The method according to claim 16, wherein forming the plating layer comprises forming a first plating layer on the thermal interface material structure over the center region, and forming a second plating layer different from the first plating layer on the thermal interface material structure over the peripheral regions.

20. The method according to claim 16, wherein the heating process is performed in a temperature range of 100° C. to 200° C.
